(19) United States
(12) Patent Application Publication
(10) Pub. No.: US 2025/0176227 A1
(43) Pub. Date: May 29, 2025

(54) MEMORY CHIP AND MANUFACTURING METHOD OF THE MEMORY CHIP

(71) Applicant: SK hynix Inc., Icheon-si Gyeonggi-do (KR)

(72) Inventor: Yun Cheol HAN, Icheon-si Gyeonggi-do (KR)

(73) Assignee: SK hynix Inc., Icheon-si Gyeonggi-do (KR)

(21) Appl. No.: 18/649,388

(22) Filed: Apr. 29, 2024

(30) Foreign Application Priority Data
Nov. 28, 2023 (KR) 10-2023-0167849

(51) Int. Cl. H01L 29/06; H01L 23/528; H01L 23/532

(52) U.S. Cl. CPC H10D 62/102; H01L 23/5283; H01L 23/53271

(57) ABSTRACT

A memory chip, and a method of manufacturing the memory chip, are provided. The memory chip includes a memory region including cell plugs in which data is stored and a guard-ring surrounding the memory region. The guard-ring includes sub-layers of the same materials arranged in the same order as layers forming the cell plugs.

### CROSS-REFERENCE TO RELATED APPLICATION

The present application claims priority under 35 U.S.C. § 119(a) to Korean patent application number 10-2023-0167849 filed on Nov. 28, 2023, in the Korean Intellectual Property Office, the entire contents of which application is incorporated herein by reference.

### BACKGROUND

### 1. Technical Field

Various embodiments of the present disclosure generally relate to a memory chip and a manufacturing method of the memory chip, and more particularly, to a memory chip including a guard-ring and a manufacturing method of the memory chip including the guard-ring.

### 2. Related Art

Memory chips may be manufactured simultaneously on a wafer.

When the manufacture of the memory chips is completed, a dicing process of cutting the wafer along a scribe lane between the memory chips may be performed. The memory chips separated from each other by the dicing process may be used to manufacture various electronic products by different packaging processes.

Each of the memory chips may include a memory region to store data and a guard-ring to protect the memory region. The memory region may include memory blocks and peripheral circuits. Devices in the memory region are manufactured by a microfabrication process. Therefore, the devices in the memory region may be vulnerable to physical shocks or chemical permeation originating from outside the memory chips during the manufacturing process. The guard-ring may be configured to protect the memory region from the external physical shocks or the chemical permeation.

As integration density of the memory chips increases, a size of the guard-ring decreases, which may degrade a function of the guard-ring.

### SUMMARY

According to an embodiment of the present disclosure, a memory chip may include a memory region including cell plugs in which data is stored and a guard-ring surrounding the memory region, wherein the guard-ring includes sub-layers of the same materials arranged in the same order as layers forming the cell plugs.

According to an embodiment of the present disclosure, a memory chip may include a cell plug and a guard-ring. The cell plug may include a first layer penetrating a stack structure in a memory region, a second layer surrounded by the first layer, a third layer surrounded by the second layer, a fourth layer surrounded by the third layer, and a fifth layer surrounded by the fourth layer. The guard-ring may be located around the memory region and may include a first sub-layer corresponding to the first layer, a second sub-layer surrounded by the first sub-layer and corresponding to the second layer, a third sub-layer surrounded by the second sub-layer and corresponding to the third layer, a fourth sub-layer surrounded by the third sub-layer and corresponding to the fourth layer, and a fifth sub-layer surrounded by the fourth sub-layer and corresponding to the fifth layer.

According to an embodiment of the present disclosure, a method of manufacturing a memory chip may include forming a stack structure over a lower structure in which a memory region and a guard region surrounding the memory region are defined, forming a first opening in the memory region of the stack structure, forming a second opening in the guard region of the stack structure, increasing a width of the second opening to change the second opening to a guard opening, and forming different layers simultaneously along surfaces of the first opening and the guard opening.

### BRIEF DESCRIPTION OF THE DRAWINGS

FIG. 1 is a diagram illustrating a wafer on which memory chips are manufactured;

FIG. 2 is a diagram illustrating a memory chip according to an embodiment of the present disclosure;

FIG. 3 is a diagram illustrating a memory region of the memory chip;

FIG. 4 is a diagram illustrating a memory cell array;

FIG. 5 is a diagram illustrating a structure of a cell plug included in a memory block;

FIG. 6 is a diagram illustrating a structure of a guard-ring according to an embodiment of the present disclosure;

FIGS. 7A to 7K are cross-sectional views illustrating a method of manufacturing a memory chip;

FIGS. 8A to 8D are plan views illustrating a method of manufacturing a memory chip;

FIG. 9 is a plan view illustrating a portion of a guard-ring;

FIG. 10 is a diagram illustrating an effect of the guard-ring according to the present disclosure; and

FIG. 11 is a diagram illustrating a structure of a guard-ring according to another embodiment of the present disclosure.

### DETAILED DESCRIPTION

Specific structural and functional descriptions disclosed herein are illustrative for the purpose of describing embodiments according to the concept of the present disclosure. Embodiments according to the concept of the present disclosure should not be construed as being limited to the specific embodiments set forth herein and can be implemented in various forms.

Hereinafter, it will be understood that, although the terms “first,” “second,” etc. may be used herein to describe various elements, these elements should not be limited by these terms. The above terms are used only to distinguish one component from another component and not to imply a number or order of components.

Some embodiments of the present disclosure relate to a memory chip capable of improving a protective function of a guard-ring and a method of manufacturing the memory chip.

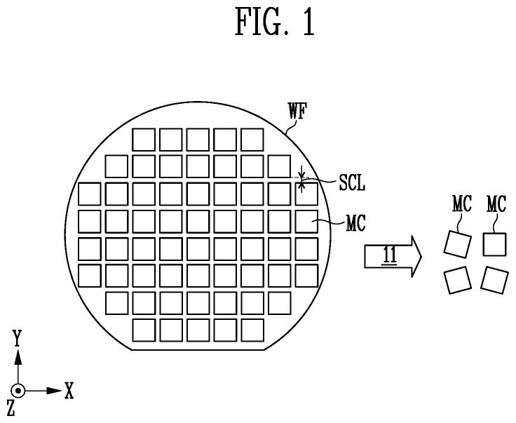

FIG. 1 is a diagram illustrating a wafer on which a plurality of memory chips MC are manufactured.

Referring to FIG. 1, the plurality of memory chips MC may be formed on the wafer WF. The wafer WF may be a substrate on which the plurality of memory chips MC may be formed. The wafer WF is shown as a circular substrate formed by cutting a single crystalline ingot to have a small thickness which is obtained by growing silicon (Si) or gallium arsenide (GaAs).

After completion 11 of a manufacturing process of the plurality of memory chips MC on the wafer WF, a dicing process of cutting the wafer WF along scribe lanes SCL may be performed. The plurality of memory chips MC may be separated from each other by the dicing process.

The plurality of memory chips MC may be manufactured as various types of memory devices, and memory chips MC manufactured on the same wafer WF may be manufactured as the same type of memory device. For example, a memory chip MC may be classified as a volatile memory device or a non-volatile memory device. A volatile memory device may lose stored data when power is not supplied. A non-volatile memory device may retain stored data even in the absence of supplied power. A volatile memory device may be a Random-Access Memory (RAM) device, and the RAM device may be classified as a Dynamic Random-Access Memory (DRAM) device or a Static Random-Access Memory (SRAM) device. Examples of a non-volatile memory device may include a NAND flash memory device, a NOR flash memory device, a Resistive Random-Access Memory (ReRAM) device, a Phase-change Random-Access Memory (PRAM) device, a Magnetoresistive Random-Access Memory (MRAM) device, a Ferroelectric Random-Access Memory (FRAM) device, or a Spin Transfer Torque Random-Access Memory (STT-RAM) device. However, the present disclosure should not be limited to the types of memory devices described above.

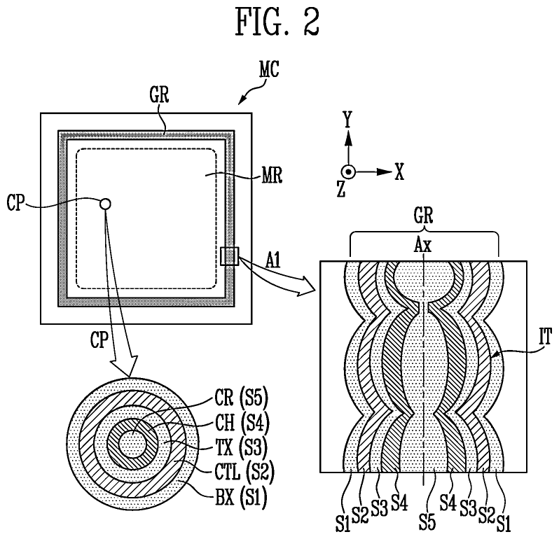

FIG. 2 is a diagram illustrating a memory chip according to an embodiment of the present disclosure.

Referring to FIG. 2, one memory chip MC is shown among the plurality of memory chips MC of FIG. 1. The memory chip MC may include a memory region MR and a guard-ring GR surrounding the memory region MR.

Devices configured to store, output, or erase data may be included in the memory region MR. For example, memory cells and peripheral circuits may be included in the memory region MR. The memory cells may be configured to store data and the peripheral circuits may be configured to perform a program, read, and erase operations. The memory cells may be formed in a cell plug CP. The cell plug CP may extend in the vertical direction with respect to a substrate. For example, assuming that the substrate defines an XY plane, the cell plug CP may extend in a Z direction perpendicular to the XY plane. The cell plug CP may include a core pillar CR, a channel layer CH, a tunnel isolation layer TX, a charge trap layer CTL, and a blocking layer BX. The core pillar CR may have a cylindrical shape or a rectangular pillar shape and may include an insulating material or a conductive material. Being insulating or conductive refers to being electrically insulating or conductive. The channel layer CH may surround the core pillar CR and may include polysilicon. The tunnel isolation layer TX may surround the channel layer CH and may include an oxide layer. The charge trap layer CTL may surround the tunnel isolation layer TX and may include a nitride layer. The blocking layer BX may surround the charge trap layer CTL and may include an oxide layer.

The guard-ring GR may include a plurality of sub-layers surrounding the memory region MR. Referring to an enlarged view of region A1 of the guard-ring GR, the guard-ring GR may include first to fifth sub-layers S1 to S5 forming a symmetrical structure with respect to a central axis Ax. For example, the guard-ring GR may include first sub-layers S1 facing each other with respect to the central axis Ax, second sub-layers S2 facing each other with respect to the central axis Ax and contacting the first sub-layers S1, respectively, third sub-layers S3 facing each other with respect to the central axis Ax and contacting the second sub-layers S2, respectively, fourth sub-layers S4 facing each other with respect to the central axis Ax and contacting the third sub-layers S3, respectively, and a fifth sub-layer S5 extending along the central axis Ax and located between the fourth sub-layers S4.

The guard-ring GR may include layers that form the cell plug CP. The first sub-layers S1 of the guard-ring GR may be the same as the blocking layer BX of the cell plug CP, the second sub-layers S2 of the guard-ring GR may be the same as the charge trap layer CTL of the cell plug CP, the third sub-layers S3 of the guard-ring GR may be the same as the tunnel isolation layer TX of the cell plug CP, the fourth sub-layers S4 of the guard-ring GR may be the same as the channel layer CH of the cell plug CP, and the fifth sub-layer S5 of the guard-ring GR may be the same as the core pillar CR of the cell plug CP.

The guard-ring GR and the cell plug CP of the memory region MR may be formed simultaneously. For example, the first sub-layers S1 of the guard-ring GR may be formed simultaneously with the blocking layer BX of the cell plug CP, the second sub-layers S2 of the guard-ring GR may be formed simultaneously with the charge trap layer CTL of the cell plug CP, the third sub-layers S3 of the guard-ring GR may be formed simultaneously with the tunnel isolation layer TX of the cell plug CP, the fourth sub-layers S4 of the guard-ring GR may be formed simultaneously with the channel layer CH of the cell plug CP, and the fifth sub-layer S5 of the guard-ring GR may be formed simultaneously with the core pillar CR of the cell plug CP. Materials of the first to fifth sub-layers S1 to S5 included in the guard-ring GR may be changed depending on materials of the blocking layer BX, the charge trap layer CTL, the tunnel isolation layer TX, the channel layer CH, and the core pillar CR included in the cell plug CP.

Accordingly, in an embodiment to be described below, the guard-ring GR including five sub-layers, for example, the first to fifth sub-layers S1 to S5 is described. However, the number and materials of sub-layers forming the guard-ring GR may be changed depending on the cell plug CP.

When the guard-ring GR includes the first to fifth sub-layers S1 to S5 contacting each other, an interface IT may be present between each pair of adjacent sub-layers among the first to fifth sub-layers S1 to S5 including different materials from each other. Accordingly, the first to fifth sub-layers S1 to S5 and different interfaces IT may prevent or mitigate an inflow of impurities.

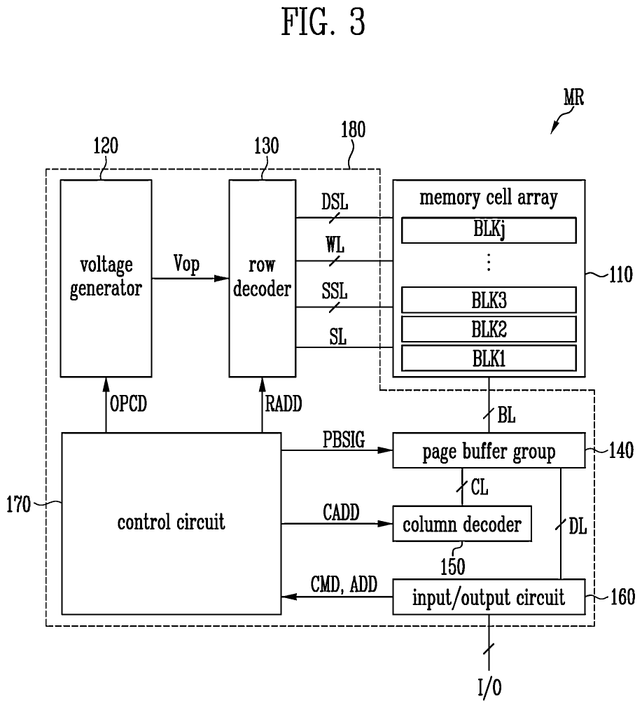

FIG. 3 is a diagram illustrating the memory region MR of the memory chip MC.

Referring to FIG. 3, the memory region MR may include a memory cell array 110 and peripheral circuits 180. The memory cell array 110 may include first to jth memory blocks BLK1 to BLKj. Each of the first to jth memory blocks BLK1 to BLKj may include memory cells capable of storing data. Drain select lines DSL, word lines WL, source select lines SSL, and a source line SL may be coupled to each of the first to jth memory blocks BLK1 to BLKj, and bit lines BL may be commonly coupled to the first to jth memory blocks BLK1 to BLKj.

The first to jth memory blocks BLK1 to BLKj may be formed in a three-dimensional structure. The memory blocks having the three-dimensional structure may include cell plugs extending in the vertical direction with respect to the substrate. Each of the cell plugs may include a plurality of memory cells and select transistors. The memory cells may store one-bit or two-or-more-bit data according to a program method. For example, a method in which one-bit data is stored in one memory cell is referred to as a single-level cell (SLC) method, and a method in which two-bit data is stored in one memory cell is referred to as a multi-level cell (MLC) method. A method in which three-bit data is stored in one memory cell is referred to as a triple-level cell (TLC) method, and a method in which four-bit data is stored in one memory cell is referred to as a quad-level cell (QLC) method. In addition, five-or-more-bit data may be stored in one memory cell.

The peripheral circuits 180 may be configured to perform a program operation for storing data in the memory cell array 110, a read operation for outputting data stored in the memory cell array 110, and an erase operation for erasing data stored in the memory cell array 110. For example, the peripheral circuits 180 may include a voltage generator 120, a row decoder 130, a page buffer group 140, a column decoder 150, an input/output circuit 160, and a control circuit 170.

The voltage generator 120 may generate various operating voltages Vop used for a program operation, a read operation, or an erase operation in response to an operation code OPCD. For example, the voltage generator 120 may be configured to generate program voltages, turn-on voltages, turn-off voltages, negative voltages, pre-charge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a selected memory block through the row decoder 130.

The program voltages may be applied to a selected word line among the word lines WL during a program operation, and may be used to increase threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltages may be set to 0V. The pre-charge voltages may be higher than 0V, and may be applied to the bit lines BL during a read operation. The verify voltages may be used during a verify operation for determining whether threshold voltages of selected memory cells have been increased to a target level. The verify voltages may be set to various levels according to the target level, and may be applied to the selected word line. The read voltages may be applied to the selected word line during a read operation of the selected memory cells. For example, the read voltages may be set to various levels according to a program method of the selected memory cells. The pass voltages may be applied to unselected word lines among the word lines WL during a program or read operation, and may be used to turn on memory cells coupled to the unselected word lines. The erase voltages may be used during an erase operation for erasing the memory cells included in the selected memory block, and may be applied to the source line SL.

The row decoder 130 may be configured to transfer the operating voltages Vop to the drain select lines DSL, the word lines WL, the source select lines SSL, and the source line SL which are coupled to the selected memory block according to a row address RADD. For example, the row decoder 130 may be coupled to the voltage generator 120 through global lines, and may be coupled to the first to jth memory blocks BLK1 to BLKj through the drain select lines DSL, the word lines WL, the source select lines SSL, and the source line SL.

The page buffer group 140 may include page buffers (not shown) respectively coupled to the first to jth memory blocks BLK1 to BLKj. Each of the page buffers (not shown) may be coupled to the first to jth memory blocks BLK1 to BLKj through the bit lines BL.

The column decoder 150 may be configured to transfer data between the page buffer group 140 and the input/output circuit 160 in response to a column address CADD. For example, the column decoder 150 may be coupled to the page buffer group 140 through column lines CL, and may transfer enable signals through the column lines CL. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transfer the command CMD and the address ADD which are received from an external controller to the control circuit 170 through the input/output lines I/O, and may transfer data received from the external controller to the page buffer group 140 through the input/output lines I/O. Alternatively, the input/output circuit 160 may output data transferred from the page buffer group 140 to the external controller through the input/output lines I/O.

The control circuit 170 may output the operation code OPCD, the row address RADD, page buffer control signals PBSIG, and the column address CADD in response to the command CMD and the address ADD. For example, when the command CMD which is input to the control circuit 170 corresponds to a program operation, the control circuit 170 may control the peripheral circuits 180 to perform the program operation of a memory block selected by the address ADD. When the command CMD which is input to the control circuit 170 corresponds to a read operation, the control circuit 170 may control the peripheral circuits 180 to perform the read operation of the memory block selected by the address ADD and to output read data. When the command CMD which is input to the control circuit 170 corresponds to an erase operation, the control circuit 170 may control the peripheral circuits 180 to perform the erase operation of the selected memory block.

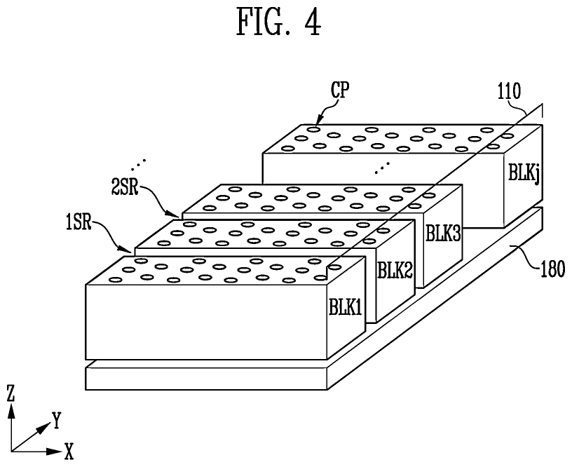

FIG. 4 is a diagram illustrating a memory cell array.

Referring to FIG. 4, the memory cell array 110 may be located over the peripheral circuits 180, but the positions of the memory cell array 110 and the peripheral circuits 180 are not limited to those shown in FIG. 4. For example, the memory cell array 110 may be located on the same plane as the peripheral circuits 180. Alternatively, the memory cell array 110 and the peripheral circuits 180 may contact each other after the memory cell array 110 and the peripheral circuits 180 are formed on different substrates.

The memory cell array 110 may include the first to jth memory blocks BLK1 to BLKj. The first to jth memory blocks BLK1 to BLKj may be spaced apart from each other in a Y direction. The first to jth memory blocks BLK1 to BLKj may be configured in the same manner as one another and may be separated from each other by slit regions 1SR, 2SR, and the like. Each of the slit regions 1SR, 2SR, and the like may extend in an X direction. For example, the first and second memory blocks BLK1 and BLK2 may be separated from each other by a first slit region 1SR.

Each of the first to jth memory blocks BLK1 to BLKj may include the cell plugs CP. For example, assuming that the substrate defines the XY plane, the cell plugs CP may extend in the Z direction perpendicular to the XY plane or may be arranged to be spaced apart from each other.

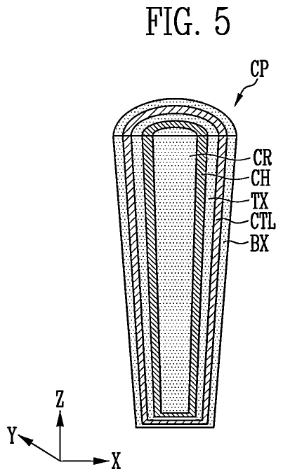

FIG. 5 is a diagram illustrating a structure of a cell plug included in a memory block and showing a cross-section of one of the cell plugs CP shown in FIG. 4 which is taken in an XZ direction.

Referring to FIG. 5, the cell plug CP may include the core pillar CR, the channel layer CH, the tunnel isolation layer TX, the charge trap layer CTL, and the blocking layer BX. The core pillar CR may have a cylindrical shape or a rectangular pillar shape and may include an insulating material or a conductive material. The channel layer CH may surround a side surface and a lower surface of the core pillar CR and may include polysilicon. The tunnel isolation layer TX may surround a side surface and a lower surface of the channel layer CH and may include an oxide layer. The charge trap layer CTL may surround a side surface and a lower surface of the tunnel isolation layer TX and may include a nitride layer. The blocking layer BX may surround a side surface and a lower surface of the charge trap layer CTL and may include an oxide layer.

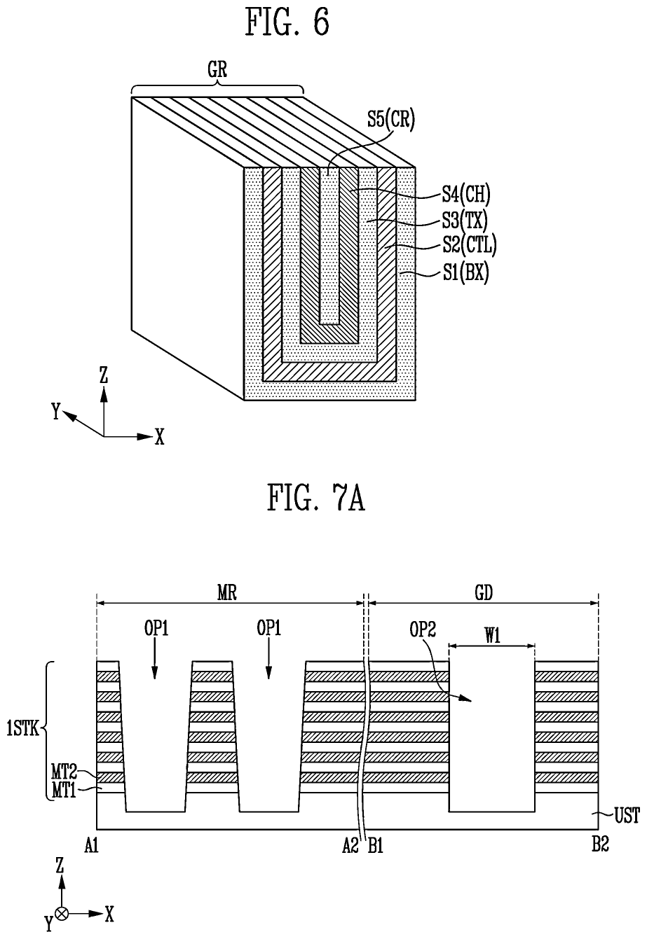

FIG. 6 is a diagram illustrating a structure of a guard-ring according to an embodiment of the present disclosure.

FIG. 6 shows a portion of the guard-ring GR included in the memory chip MC which extends in the Y direction. The guard-ring GR may include the first to fifth sub-layers S1 to S5. The fifth sub-layer S5 may have a linear shape extending in the Y direction. A height of the fifth sub-layer S5 in the Z direction may be changed depending on a depth of a trench in which the guard-ring GR is formed. The fifth sub-layer S5 may correspond to the core pillar CR of the cell plug CP. The fourth sub-layer S4 may surround a side surface and a lower surface of the fifth sub-layer S5 and may correspond to the channel layer CH of the cell plug CP. The third sub-layer S3 may surround a side surface and a lower surface of the fourth sub-layer S4 and may correspond to the tunnel isolation layer TX of the cell plug CP. The second sub-layer S2 may surround a side surface and a lower surface of the third sub-layer S3 and may correspond to the charge trap layer CTL of the cell plug CP. The first sub-layer S1 may surround a side surface and a lower surface of the second sub-layer S2 and may correspond to the blocking layer BX of the cell plug CP.

A cross-section of the first sub-layer S1 may have a tubular shape surrounding the second sub-layer S2. A cross-section of the second sub-layer S2 may have a tubular shape surrounding the third sub-layer S3. A cross-section of the third sub-layer S3 may have a tubular shape surrounding the fourth sub-layer S4. A cross-section of the fourth sub-layer S4 may have a tubular shape surrounding the fifth sub-layer S5. For some embodiments, the tubular shape can have a variable diameter along the longitudinal axis of the tube. The fifth sub-layer S5 may have a linear shape along the longitudinal axis of the tube.

The guard-ring GR according to an embodiment of the present application may be formed simultaneously with the cell plugs CP in the memory region MR. A manufacturing method of a memory chip including the cell plugs CP and the guard-ring GR is described as follows.

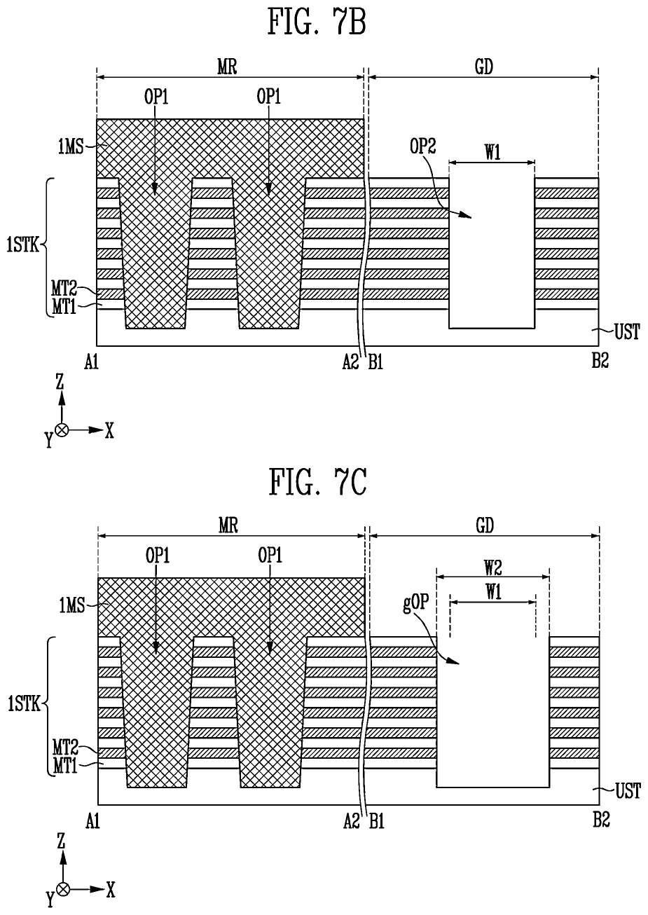

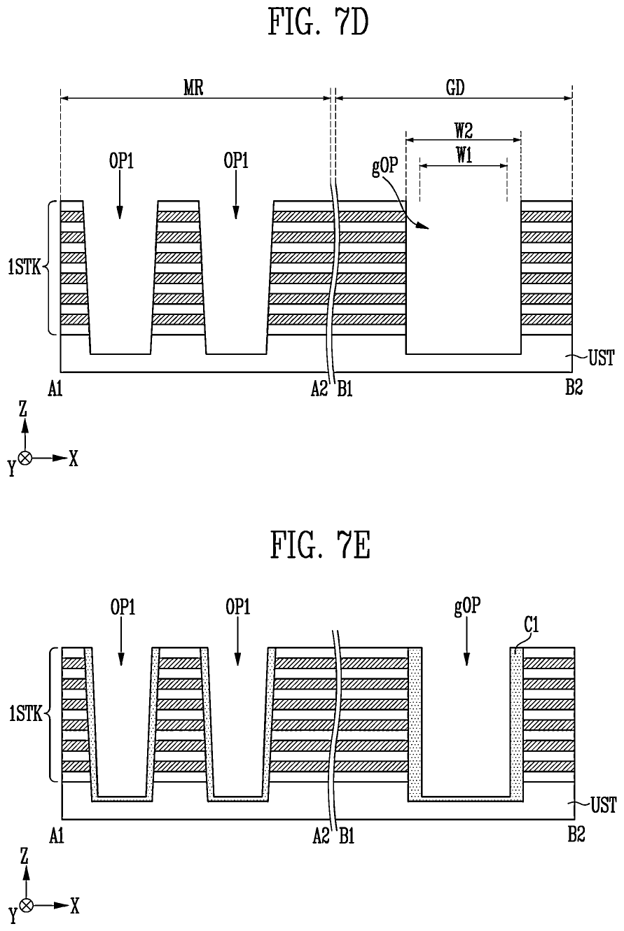

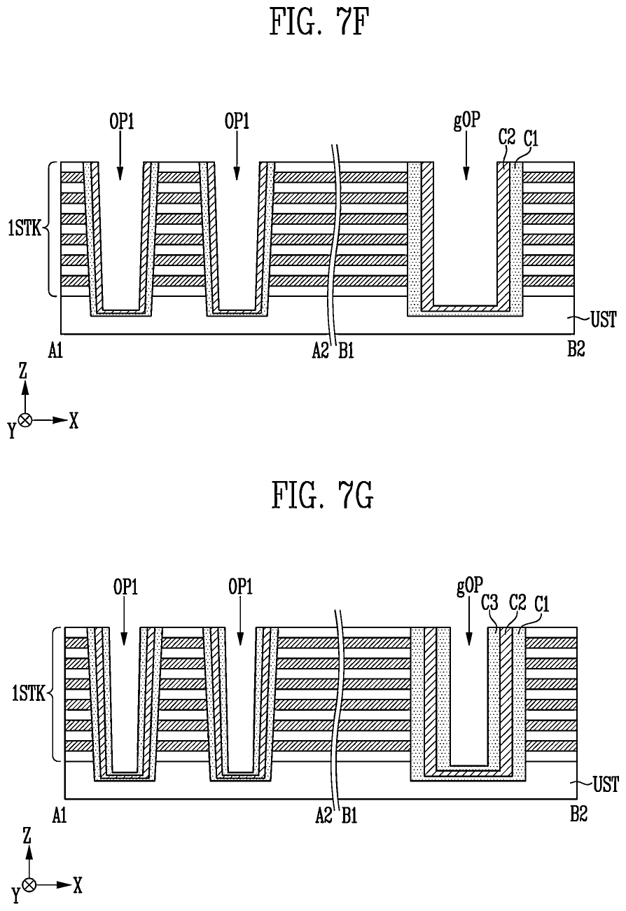

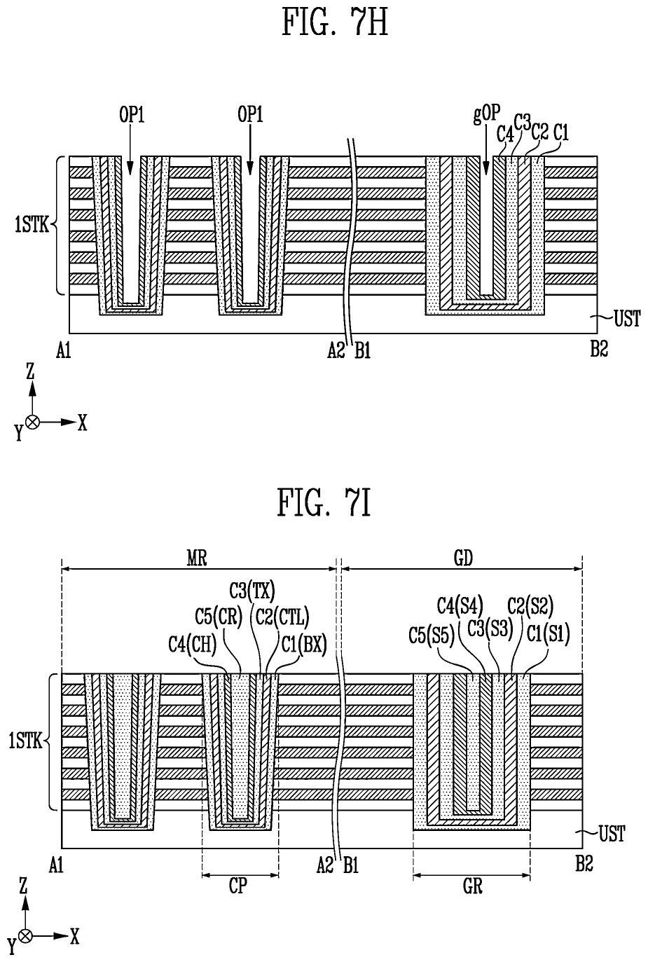

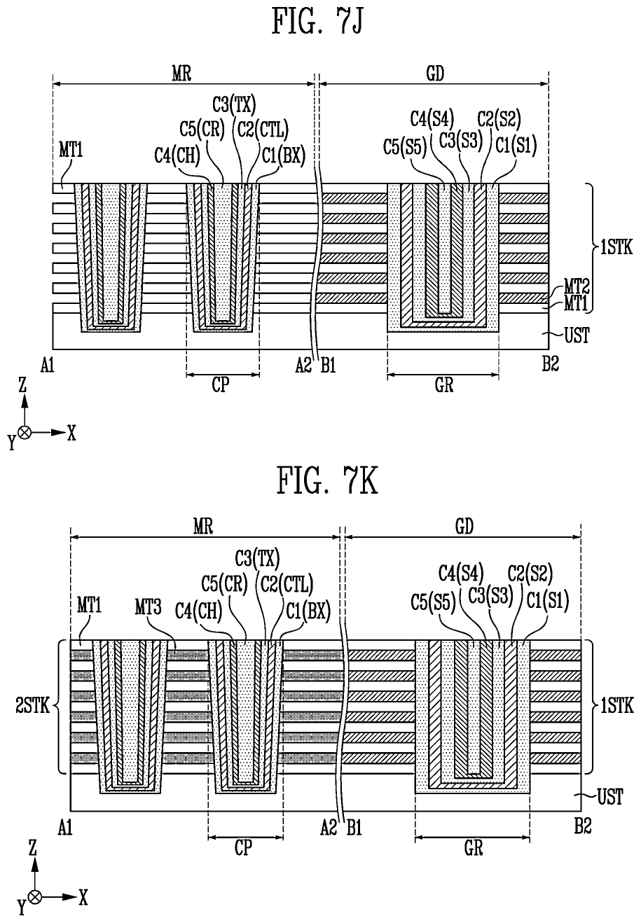

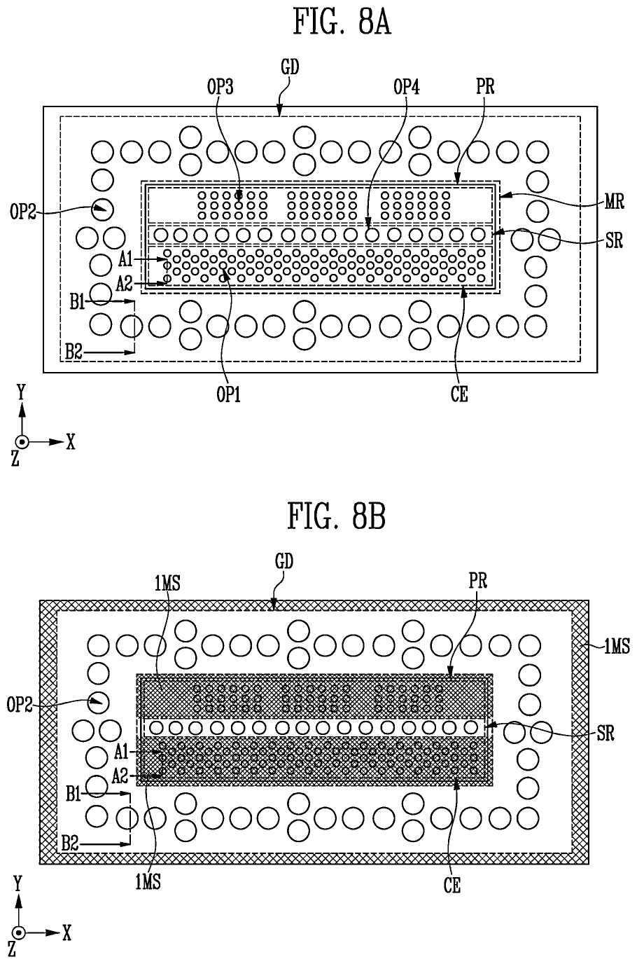

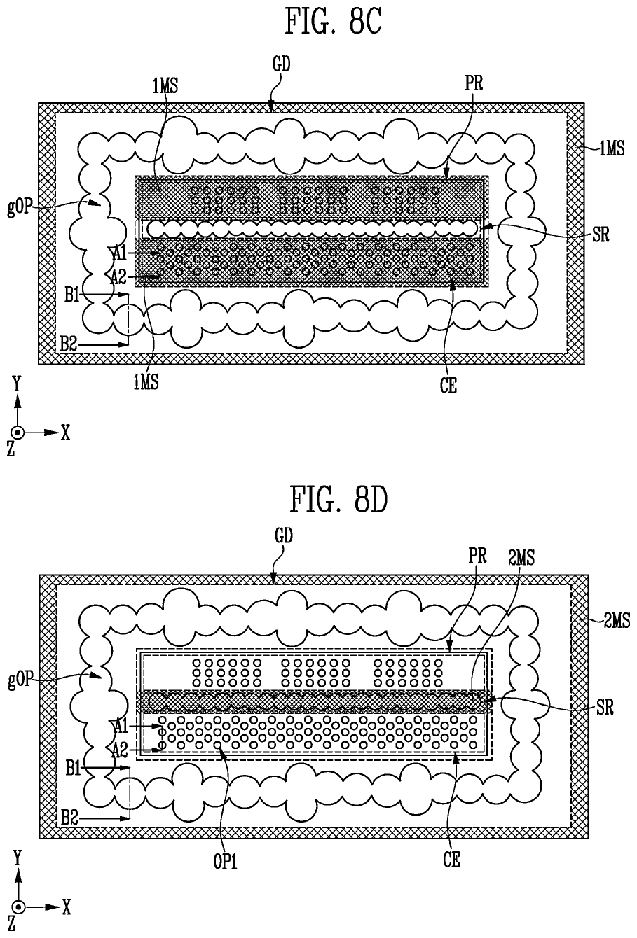

FIGS. 7A to 7K are cross-sectional views illustrating a method of manufacturing a memory chip, and FIGS. 8A to 8D are plan views illustrating a method of manufacturing a memory chip.

Referring to FIGS. 7A and 8A, a first stack structure 1STK may be formed on a lower structure UST in which the memory region MR and a guard region GD are defined. For example, the first stack structure 1STK may be formed above the lower structure UST in the Z direction. The lower structure UST may be a substrate or a peripheral circuit structure. The first stack structure 1STK may include first material layers MT1 and second material layers MT2 which are different from each other. The first material layers MT1 and the second material layers MT2 may be alternately stacked. For example, the first material layers MT1 may be oxide layers and the second material layers MT2 may be nitride layers.

First openings OP1 penetrating the first stack structure 1STK in the memory region MR to expose a portion of the lower structure UST and second openings OP2 penetrating the first stack structure 1STK in the guard region GD to expose a portion of the lower structure UST may be formed simultaneously. Each of the first openings OP1 and the second openings OP2 may be formed to have a hole shape. For example, each of the first openings OP1 and the second openings OP2 may be formed to have a hole shape with an elliptical cross section, a circular cross section, or a rectangular cross section. The first openings OP1 may be formed in the memory region MR and the second openings OP2 may be formed in the guard region GD. An etching process to form the first openings OP1 and the second openings OP2 may be performed using an anisotropic dry etching method. The etching process may be performed to expose a portion of the lower structure UST. In an embodiment, it is assumed that a width of each of the second openings OP2 formed by the anisotropic dry etching process is a first width W1.

When the first openings OP1 and the second openings OP2 are formed, holes may be formed simultaneously in other regions in the memory region MR. For example, the memory region MR may include a cell region CE, a peripheral region PR, and a slit region SR. In a subsequent process, memory blocks including the memory cells may be formed in the cell region CE, peripheral circuits may be formed in the peripheral region PR, and slits dividing the memory blocks may be formed in the slit region SR.

The first openings OP1 may be formed in the cell region CE. Third openings OP3 may be formed in a region in the peripheral region PR, where contacts electrically coupling devices in the cell region CE and the peripheral circuits in the peripheral region PR are to be formed. Fourth openings OP4, which are spaced apart from each other in the X direction, may be formed in the slit region SR.

Referring to FIGS. 7B and 8B, a first mask pattern 1MS in which the guard region GD and the slit region SR are opened may be formed on the first stack structure 1STK. For example, the second openings OP2 formed in the guard region GD and the fourth openings OP4 formed in the slit region SR may be exposed through openings in the first mask pattern 1MS.

Referring to FIGS. 7C and 8C, an etching process may be performed to increase a size of each of the second openings OP2 and the fourth openings OP4 which are exposed through the openings of the first mask pattern 1MS. Here, the size of each of the second openings OP2 and the fourth openings OP4 refers to a diameter or a width of each of the second openings OP2 and the fourth openings OP4. The etching process may be performed to overlap the second openings OP2 arranged in the X direction with each other and to overlap the second openings OP2 arranged in the Y direction with each other. The etching process may be performed by a wet etching process or an isotropic dry etching process. When the wet etching process or the isotropic dry etching process is performed, portions of a side surface and a lower surface of each of the second openings OP2 and the fourth openings OP4 may be removed. Accordingly, the diameter or the width of each of the second openings OP2 and the fourth openings OP4 may be increased. For example, the width of each of the second openings OP2 may be increased to a second width W2, which is greater than the first width W1, by the wet etching process or the isotropic dry etching process. When the diameter or the width of each of the second openings OP2 increases and the adjacent second openings OP2 overlap and merge with each other, the second openings OP2 may be changed to a continuous guard opening gOP that extends to surround the cell region CE, the peripheral region PR, and the slit region SR.

Referring to FIGS. 7D and 8D, after the first mask pattern 1MS is removed, a second mask pattern 2MS in which the guard region GD, the cell region CE and the peripheral region PR are opened may be formed. For example, the second mask pattern 2MS may block the slit region SR and a scribe lane region. The scribe lane region may surround the guard region GD. The guard opening gOP and the first openings OP1 may be exposed by the second mask pattern 2MS. In FIG. 8D, it is illustrated that the holes formed in the peripheral region PR are also exposed. However, embodiments are not limited thereto, and the second mask pattern 2MS may be formed to block the holes formed in the peripheral region PR.

Referring to FIG. 7E, a first layer C1 may be formed along a surface of each of the first openings OP1 and the guard opening gOP. For example, the first layer C1 may be formed along a side surface and a lower surface of each of the first openings OP1 and the guard opening gOP. The first layer C1 may be an insulating layer. For example, the first layer C1 may be an oxide layer.

Referring to FIG. 7F, a second layer C2 may be formed along a surface of the first layer C1. For example, the second layer C2 may be formed along the side surface and the lower surface of each of the first openings OP1 and the guard opening gOP which are covered with the first layer C1. The second layer C2 may be a nitride layer.

Referring to FIG. 7G, a third layer C3 may be formed along a surface of the second layer C2. For example, the third layer C3 may be formed along the side surface and the lower surface of each of the first openings OP1 and the guard opening gOP which are covered with the second layer C2. The third layer C3 may be an insulating layer. For example, the third layer C3 may be an oxide layer.

Referring to FIG. 7H, a fourth layer C4 may be formed along a surface of the third layer C3. For example, the fourth layer C4 may be formed along the side surface and the lower surface of each of the first openings OP1 and the guard opening gOP which are covered with the third layer C3. The fourth layer C4 may be polysilicon.

Referring to FIG. 7I, a region surrounded by the fourth layer C4 may be filled with a fifth layer C5. The fifth layer C5 may be an insulating layer or a conductive layer. Thus, the first to fifth layers C1 to C5 formed in the memory region MR may be the cell plug CP and the first to fifth layers C1 to C5 formed in the guard region GD may be the guard-ring GR. The first layer C1 of the cell plug CP may correspond to the blocking layer BX, the second layer C2 of the cell plug CP may correspond to the charge trap layer CTL, the third layer C3 of the cell plug CP may correspond to the tunnel isolation layer TX, the fourth layer C4 of the cell plug CP may correspond to the channel layer CH, and the fifth layer C5 of the cell plug CP may correspond to the core pillar CR.

The first layer C1 of the guard-ring GR may correspond to the first sub-layers S1, the second layer C2 of the guard-ring GR may correspond to the second sub-layers S2, the third layer C3 of the guard-ring GR may correspond to the third sub-layers S3, the fourth layer C4 of the guard-ring GR may correspond to the fourth sub-layers S4, and the fifth layer C5 of the guard-ring GR may correspond to the fifth sub-layer S5.

Referring to FIG. 7J, an etching process may be performed to remove the second material layers MT2 from the first stack structure 1STK in the memory region MR. For example, an isotropic dry etching process or a wet etching process may be performed. The etching process may be performed using gas or etchant with higher etch selectivity with respect to the second material layers MT2 than the first material layers MT1. Although it is not illustrated in the drawing, an isolation structure (not shown) separating the first stack structure 1STK may be formed between the memory region MR and the guard region GD, and due to the isolation structure (not shown), the first stack structure 1STK in the guard region GD may remain.

Referring to FIG. 7K, third material layers M3 may be formed between the first material layers M1. The third material layers M3 may be used as gate lines of the memory blocks. Accordingly, the third material layers M3 may include a conductive layer. For example, the third material layers M3 may include metal materials such as tungsten (W), molybdenum (Mo), cobalt (Co), or nickel (Ni), or may include semiconductor materials such as silicon (Si) or polysilicon (Poly-Si). However, materials for the third material layers M3 are not necessarily limited to the materials specifically indicated above.

As it is described with reference to FIGS. 7A to 7K and FIGS. 8A to 8D, the guard-ring GR according to an embodiment of the present disclosure is formed simultaneously with the cell plugs CP in the memory region MR. Therefore, the manufacturing time may be reduced compared to a process in which the guard-ring GR is formed separately from the cell plugs CP.

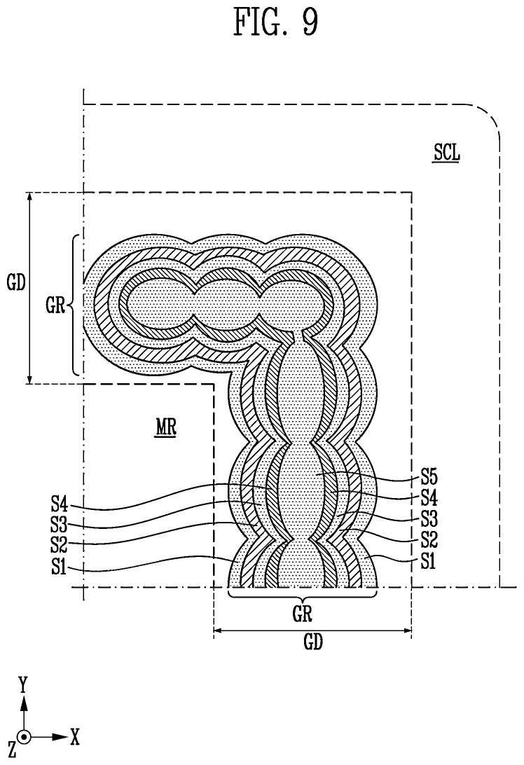

FIG. 9 is a plan view illustrating a portion of a guard-ring.

Referring to FIG. 9, a portion of the memory chip is illustrated. The guard-ring GR of the memory chip is located in the guard region GD of the memory chip and may extend in orthogonal directions from the corners. The guard region GD may be surrounded by a scribe lane SCL. In a plan view, the first to fifth sub-layers S1 to S5 forming the guard-ring GR may have a layout in which a plurality of ovals or circles are overlapped.

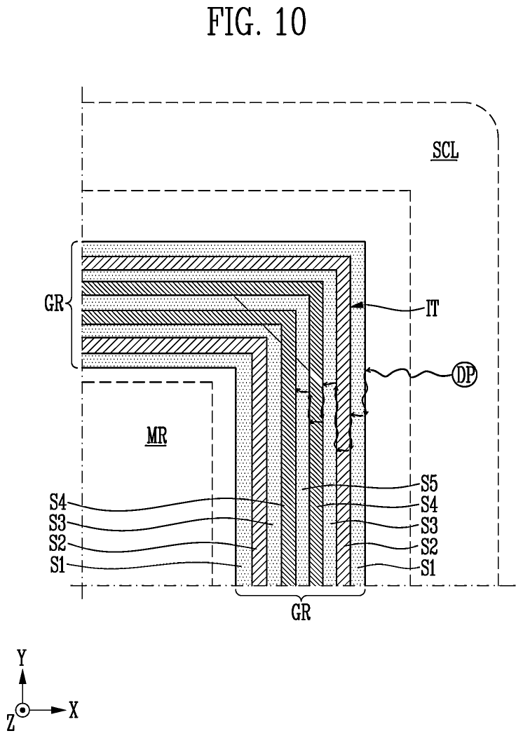

FIG. 10 is a diagram illustrating an effect of the guard-ring according to the present disclosure.

Referring to FIG. 10, the guard-ring GR may have a linear shape extending in each of the X direction and the Y direction. The guard-ring GR of the memory chip may be extended to form a right angle at the corners of the memory chip. The memory chip may be surrounded by the scribe lane SCL. Because the first to fifth sub-layers S1 to S5 contacting each other form the guard-ring GR, the interfaces IT may be formed between the first to fifth sub-layers S1 to S5 contacting each other.

When impurities DP are introduced into the memory chip from outside of the memory chip during the manufacturing process of the memory chip, the impurities DP may come into contact with the first sub-layer S1 first. When the film quality of a portion of the first sub-layer S1 that contacts the impurities DP is sturdy, the impurities DP might not penetrate the first sub-layer S1 and may move along the interface IT between an external layer surrounding the first sub-layer S1 and the first sub-layer S1. When a pin hole is formed in a portion of the first sub-layer S1, the impurities DP may penetrate the first sub-layer S1 along the pin hole and may reach the second sub-layer S2. The pin hole may be a defect that may occur during the manufacturing process of the memory chip and may be a hole-type defect that may occur in a heat treatment processes, etching processes, or cleaning processes. During the manufacturing process of the memory chip, the pin hole may occur in an unexpected region. Even when a pin hole is formed in a portion of the first sub-layer S1, a pin hole might not be formed in the second sub-layer S2. When the pin hole is formed in the first sub-layer S1 but not in the second sub-layer S2, the impurities DP may reach the interface IT between the first sub-layer S1 and the second sub-layer S2, but might not penetrate the second sub-layer S2. Even when a pin hole is formed in a portion of the second sub-layer S2, a pin hole might not be formed in the third sub-layer S3. When the pin hole is formed in the second sub-layer S2 but not in the third sub-layer S3, the impurities DP may reach the interface IT between the second sub-layer S2 and the third sub-layer S3, but might not penetrate the third sub-layer S3. Accordingly, the introduction of impurities into the memory region MR as well as oxidation of the memory region MR may be suppressed.

Because the types of impurities DP may vary depending on the manufacturing process of the memory chip, materials that the impurities DP may penetrate may differ. In the guard-ring GR according to an embodiment of the present disclosure, the first to fifth sub-layers S1 to S5, which include different materials from each other, may contact each other. Therefore, even when different types of impurities DP are introduced, a region into which the impurities DP may diffuse or penetrate may be limited.

Accordingly, it may be difficult for the impurities DP to penetrate all of the first to fifth sub-layers S1 to S5 included in the guard-ring GR to reach the memory region MR. As a result, the reliability of the memory region MR may be enhanced.

According to an embodiment, the first to fourth sub-layers S1 to S4 of the guard-ring GR, and more particularly, each pair of the first, second, third, and fourth sub-layers S1, S2, S3, and S4 may have a symmetrical structure with respect to the fifth sub-layer S5. Accordingly, even when the impurities DP penetrate a specific sub-layer among the first to fourth sub-layers S1 to S4, to reach the memory region MR, the impurities DP need to also penetrate a counterpart of the specific sub-layer of a corresponding pair. As a result, the probability of the impurities DP penetrating the guard-ring GR may be reduced and therefore the reliability of the memory region MR may be enhanced.

According to an embodiment, the guard-ring GR includes a plurality of different sub-layers, for example, the first to fifth sub-layers S1 to S5, which extend in the X and Y directions in the memory chip, and therefore stress applied to the wafer in the X direction or the Y direction may be reduced. Accordingly, the phenomenon of wafer bending may be reduced.

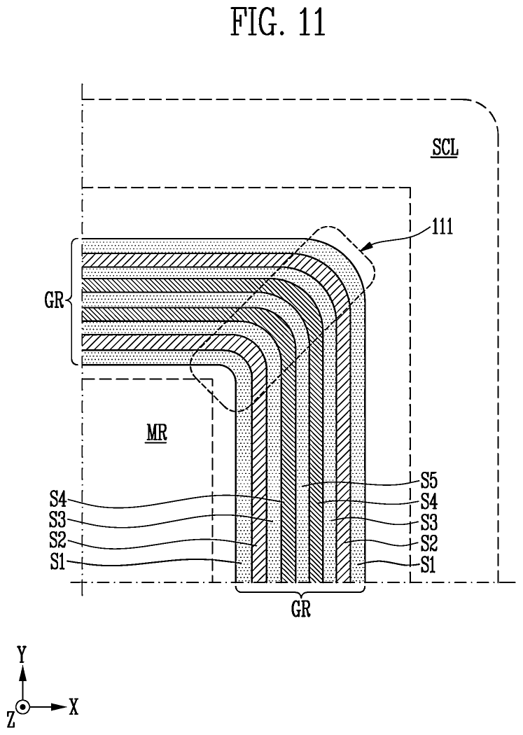

FIG. 11 is a diagram illustrating a structure of a guard-ring according to another embodiment of the present disclosure.

Referring to FIG. 11, the first to fifth sub-layers S1 to S5 may form a curved surface at corner region 111 of the guard-ring GR but not a right angle. In this type of layout, even when impurities are introduced into the guard-ring GR from outside, the phenomenon of impurities being concentrated at the edge region 111 may be reduced.

According to embodiments of the present disclosure, a protective function of a guard-ring may be improved and a defect in a memory region surrounded by the guard-ring may be prevented or mitigated. Accordingly, yield of a memory chip may be improved.

What is claimed is:

1. A memory chip, comprising:
a memory region including cell plugs in which data is stored; and
a guard-ring surrounding the memory region,
wherein the guard-ring includes sub-layers of the same materials arranged in the same order as layers forming the cell plugs.

2. The memory chip of claim 1, wherein the sub-layers have a symmetrical structure with respect to a layer which is located at a center of the guard-ring.

3. The memory chip of claim 1, wherein sub-layers contacting each other among the sub-layers include different materials from each other.

4. The memory chip of claim 1, wherein the sub-layers comprise:
first sub-layers located at an outermost side of the guard-ring and facing each other;
second sub-layers respectively contacting inner surfaces of the first sub-layers and facing each other;
third sub-layers respectively contacting inner surfaces of the second sub-layers and facing each other;
fourth sub-layers respectively contacting inner surfaces of the third sub-layers and facing each other; and
a fifth sub-layer located between the fourth sub-layers.

5. The memory chip of claim 4, wherein the fifth sub-layer contacts inner surfaces of the fourth sub-layers.

6. The memory chip of claim 4, wherein each of the first sub-layers, the third sub-layers, and the fifth sub-layer is an insulating layer.

7. The memory chip of claim 6, wherein the insulating layer is an oxide layer.

8. The memory chip of claim 4, wherein each of the second sub-layers is a nitride layer.

9. The memory chip of claim 4, wherein each of the fourth sub-layers is polysilicon.

10. The memory chip of claim 1, wherein a side of the guard-ring has a curved shape.

11. A memory chip, comprising:
a cell plug including a first layer penetrating a stack structure in a memory region, a second layer surrounded by the first layer, a third layer surrounded by the second layer, a fourth layer surrounded by the third layer, and a fifth layer surrounded by the fourth layer; and
a guard-ring located around the memory region,
wherein the guard-ring includes:
a first sub-layer corresponding to the first layer;
a second sub-layer surrounded by the first sub-layer and corresponding to the second layer;
a third sub-layer surrounded by the second sub-layer and corresponding to the third layer;
a fourth sub-layer surrounded by the third sub-layer and corresponding to the fourth layer; and
a fifth sub-layer surrounded by the fourth sub-layer and corresponding to the fifth layer.

12. The memory chip of claim 11, wherein, in a cross-section of the guard-ring taken along a direction orthogonal to a direction in which the guard-ring extends, each of the first to fourth sub-layers has a tubular shape and the fifth sub-layer has a linear shape.

13. The memory chip of claim 11, wherein each of the first layer, the third layer, the fifth layer, the first sub-layer, the third sub-layer, and the fifth sub-layer is an insulating layer.

14. The memory chip of claim 13, wherein the insulating layer is an oxide layer.

15. The memory chip of claim 11, wherein each of the second layer and the second sub-layer is a nitride layer.

16. The memory chip of claim 11, wherein each of the fourth layer and the fourth sub-layer is polysilicon.

17. A method of manufacturing a memory chip, the method comprising:
forming a stack structure over a lower structure in which a memory region and a guard region surrounding the memory region are defined;
forming a first opening in the memory region of the stack structure;
forming a second opening in the guard region of the stack structure;
increasing a width of the second opening and changing the second opening to a guard opening; and
forming different layers simultaneously along surfaces of the first opening and the guard opening.

18. The method of claim 17, wherein the first opening and the second opening are formed by the same etching process.

19. The method of claim 18, wherein the first opening and the second opening are formed simultaneously.

20. The method of claim 17, wherein an etching process for forming the first opening and the second opening is performed until a portion of the lower structure is exposed.

21. The method of claim 17, wherein forming the different layers simultaneously comprises:
forming a first layer along each of the surfaces of the first opening and the guard opening;
forming a second layer along a surface of the first layer formed in each of the first opening and the guard opening;
forming a third layer along a surface of the second layer formed in each of the first opening and the guard opening;
forming a fourth layer along a surface of the third layer formed in each of the first opening and the guard opening; and
forming a fifth layer along a surface of the fourth layer formed in each of the first opening and the guard opening.

22. The method of claim 21, wherein each of the first layer, the third layer, and the fifth layer includes an insulating layer.

23. The method of claim 21, wherein the second layer includes a nitride layer.

24. The method of claim 21, wherein the fourth layer includes polysilicon.
